(19) United States
(12) Patent Application Publication
(10) Pub. No.: US 2020/0243348 A1
(43) Pub. Date: Jul. 30, 2020

(54) METHOD FOR MANUFACTURING SEMICONDUCTOR MODULE

(71) Applicant: TOYOTA JIDOSHA KABUSHIKI KAISHA, Toyota-shi (JP)

(72) Inventor: Tomohiro TAKENAGA, Seto-shi (JP)

(73) Assignee: TOYOTA JIDOSHA KABUSHIKI KAISHA, Toyota-shi (JP)

(21) Appl. No.: 16/722,151

(22) Filed: Dec. 20, 2019

(30) Foreign Application Priority Data
Jan. 25, 2019 (JP) 2019-011255

(51) Int. Cl. H01L 21/48

(52) U.S. Cl. CPC H01L 21/4867; H01L 21/4853; H01L 21/486

(57) ABSTRACT

A method for manufacturing a semiconductor module that can appropriately fill a region sandwiched between a pair of lead frames disposed on both surfaces of a semiconductor element with a liquid thermosetting resin and reduce a time required for the filling is provided. A method for manufacturing a semiconductor module including a semiconductor element, a pair of lead frames facing each other on both surfaces of the semiconductor element, and a lead terminal protruding from each one of the pair of lead frames includes forming a penetrating hole in at least one place on one of the pair of lead frames, disposing the pair of lead frames to sandwich the both surfaces of the semiconductor element, injecting a liquid thermosetting resin through the penetrating hole to fill a region sandwiched between the pair of lead frames with the resin, and heating and curing the resin the region is filled with.

### CROSS REFERENCE TO RELATED APPLICATIONS

This application is based upon and claims the benefit of priority from Japanese patent application No. 2019-011255, filed on Jan. 25, 2019, the disclosure of which is incorporated herein in its entirety by reference.

### BACKGROUND

The present disclosure relates to a method for manufacturing a semiconductor module.

In a semiconductor module including a semiconductor element (semiconductor chip), a technique for filling a gap between the semiconductor modules is known with a liquid thermosetting resin (underfill material). Japanese Unexamined Patent Application Publication No. 2013-138177 describes a technique for dripping an underfill material into a gap between semiconductor chips by a dispenser in a method for manufacturing a semiconductor module in which a plurality of semiconductor chips are stacked and mounted.

### SUMMARY

In a semiconductor module, a semiconductor element releases a large amount of heat upon an increase in the speed and an improvement in the functionality of the semiconductor element. For this reason, a cooling mechanism for cooling the semiconductor element is necessary. Commonly, a lead frame is used as a cooling mechanism for a semiconductor element. The inventors have studied a method for filling a region sandwiched between a pair of lead frames with an underfill material in a semiconductor module having a configuration in which a semiconductor element is disposed in the region sandwiched between the pair of lead frames facing each other.

FIG. 14 shows a method for filling a region sandwiched between a pair of lead frames 531 and 532 with an underfill material 7, which has been preliminarily studied by the inventors. As shown in FIG. 14, a semiconductor element 2 and a spacer 506 for transferring heat from the semiconductor element 2 to the lead frame 531 are disposed in a region sandwiched between the pair of lead frames 531 and 532. The semiconductor element 2, the spacer 506, and the pair of lead frames 531 and 532 are coupled by solder 505. The underfill material 7 is injected by a dispenser 21 from outer edges of the pair of lead frames 531 and 532 into the region sandwiched between the pair of lead frames 531 and 532. However, it has been found that when the underfill material is injected from the outer edges of the pair of lead frames, the concentration of the constituent components of the filled underfill material in the region near the semiconductor element differs from that in the other regions. Furthermore, it has also been found that in the above method, it is difficult to inject the underfill material 7, and in order to apply the above method for mass production, the time required to fill the region sandwiched between the pair of lead frames 531 and 532 with the underfill material 7 needs to be further shortened.

The present disclosure has been made in view of the above circumstances. An object of the present disclosure is to provide a method for manufacturing a semiconductor module that can appropriately fill a region sandwiched between a pair of lead frames disposed on both surfaces of a semiconductor element with a liquid thermosetting resin and that can reduce a time required for the filling.

An example aspect is a method for manufacturing a semiconductor module including a semiconductor element, a pair of lead frames disposed to face each other on both surfaces of the semiconductor element, and a lead terminal protruding from each one of the pair of lead frames. The method includes a step of forming a penetrating hole in at least one place on one of the pair of lead frames, a step of disposing the pair of lead frames so as to sandwich the both surfaces of the semiconductor element, a step of injecting a liquid thermosetting resin through the penetrating hole to fill a region sandwiched between the pair of lead frames with the resin, and a step of heating and curing the resin filled in the region.

Commonly, an inorganic filler such as silica and alumina and an organic filler are added to the resin that the semiconductor module is filled with, in addition to the base component and curing agent that serve as a base. When the penetrating hole is formed in at least one place on one of the lead frames and the resin is injected from this penetrating hole, the resin can easily enter the region sandwiched between the pair of lead frames. Thus, the region can be appropriately filled with the resin in such a way that the content of the additive becomes more uniform. Further, the time required for the filling can be shortened.

Further, a plurality of the semiconductor elements may be present in the semiconductor module, and the penetrating hole may be formed in the vicinity of a semiconductor element having a largest amount of heat generation among the plurality of the semiconductor elements present in the semiconductor module.

Commonly, a component that promotes heat conduction such as alumina is added to the resin that the semiconductor module is filled with. When the resin is injected from the penetrating hole, in the region sandwiched between the pair of lead frames, a content ratio of the additive in the resin is higher at the position closer to the penetrating hole is closer to the content ratio of the additive in the resin before the resin is injected than that at the position farther from the penetrating hole. In other words, the content ratio of the additive contained in the resin at a position close to the penetrating hole is higher than that at a position far from the penetrating hole. Therefore, in the semiconductor module, by forming the penetrating hole in the vicinity of the semiconductor element where the amount of heat generation becomes large, it is possible to efficiently dissipate heat of the semiconductor element.

The method may further include coating an end part of the lead terminal on a side connected to the pair of lead frames with an insulating material.

In semiconductor modules, it is necessary to properly insulate the semiconductor element from the lead terminal. End parts of the lead terminals on the side of the end parts connected to the pair of the lead frames are close to the semiconductor element. By coating the end parts with the insulating material, it is possible to more satisfactory insulate the semiconductor element from the lead terminal.

According to the present disclosure, it is possible to appropriately fill a region sandwiched between a pair of lead frames disposed on both surfaces of a semiconductor element with a liquid thermosetting resin and reduce a time required for the filling.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a schematic diagram showing an example of a configuration of a semiconductor module to which a method for manufacturing a semiconductor module is applied according to a first embodiment;

FIG. 2 is a schematic diagram specifically describing each step of the method for manufacturing a semiconductor module according to the first embodiment;

FIG. 3 is a schematic diagram specifically describing each step of the method for manufacturing a semiconductor module according to the first embodiment;

FIG. 4 is a schematic diagram specifically describing each step of the method for manufacturing a semiconductor module according to the first embodiment;

FIG. 5 is a schematic diagram specifically describing each step of the method for manufacturing a semiconductor module according to the first embodiment;

FIG. 6 is a flowchart showing a process flow of the method for manufacturing a semiconductor module according to the first embodiment;

FIG. 7 is a perspective view showing an external appearance of a semiconductor module to which a method for manufacturing a semiconductor module is applied according to a second embodiment;

FIG. 8 is a perspective view showing a state in which a part of the semiconductor module shown in FIG. 7 sealed with an underfill material is removed;

FIG. 9 is a cross-sectional view taken along the line VIII-VIII in FIG. 8;

FIG. 10 is an enlarged view of a region B in FIG. 9;

FIG. 11 is an enlarged view of a region C in FIG. 9;

FIG. 12 is an enlarged view of a region D in FIG. 11;

FIG. 13 is a flowchart showing a process flow of the method for manufacturing a semiconductor module according to the second embodiment; and

FIG. 14 is a method for filling a region sandwiched between a pair of lead frames with an underfill material, which has been preliminarily studied by the inventors.

### DESCRIPTION OF EMBODIMENTS

Hereinafter, the present disclosure will be described through embodiments of the disclosure, but the disclosure according to the claims is not limited to the following embodiments. Moreover, all of the configurations described in the embodiments are not necessarily essential as means for solving the problem. For clarity of descriptions, the following descriptions and drawings are omitted and simplified as appropriate. In the drawings, the same elements are denoted by the same reference numerals, and repeated description is omitted as necessary.

### First Embodiment

Hereinafter, a first embodiment of the present disclosure will be described with reference to the drawings.

First, a configuration of a semiconductor module to which a method for manufacturing a semiconductor module is applied according to the first embodiment will be described with reference to FIG. 1. FIG. 1 is a schematic diagram showing an example of a configuration of a semiconductor module 1 to which the method for manufacturing a semiconductor module according to the first embodiment is applied. As shown in FIG. 1, the semiconductor module 1 includes a semiconductor element 2, a pair of lead frames 3 which include an upper lead frame 31 and a lower lead frame 32, and lead terminals 4.

The semiconductor element 2 is, for example, a diode or an Insulated Gate Bipolar Transistor (IGBT). The upper lead frame 31 and the lower lead frame 32, which are the pair of lead frames 3, are disposed in such a way that they face each other on both surfaces of the semiconductor element 2. The upper lead frame 31 and the lower lead frame 32 are thin metal plates used as internal wiring in the semiconductor module 1 and are formed of metal having high electrical conductivity such as copper. Further, the upper lead frame 31 and the lower lead frame 32 are positioned between the semiconductor element 2, which is a heat generator, and a radiator. The upper lead frame 31 and the lower lead frame 32 also serve as heat spreaders which are buffers for improving the heat dissipation efficiency of the radiator.

The lead terminal 4 protrudes from each of the upper lead frame 31 and the lower lead frame 32. The semiconductor element 2 is coupled to the upper lead frame 31 with a spacer 6 interposed therebetween. An end part of the lead terminal 4 protruding from the upper lead frame 31 on the side of the end part connected to the upper lead frame 31 is coated with an insulating material 9. Another end part of the lead terminal 4 protruding from the lower lead frame 32 on the side of the end part connected to the lower lead frame 32 is coated with the insulating material 9.

The spacer 6 is made of the same metal as that of the upper lead frame 31. The upper lead frame 31 is coupled to the spacer 6 by solder 5, the spacer 6 is coupled to the semiconductor element 2 by the solder 5, and the semiconductor element 2 is coupled to the lower lead frame 32 by the solder 5. The solder 5 is reflow solder. A region between the pair of lead frames 3 is filled with an underfill material 7 which is a thermosetting resin.

Next, a method for manufacturing a semiconductor module according to the first embodiment will be described.

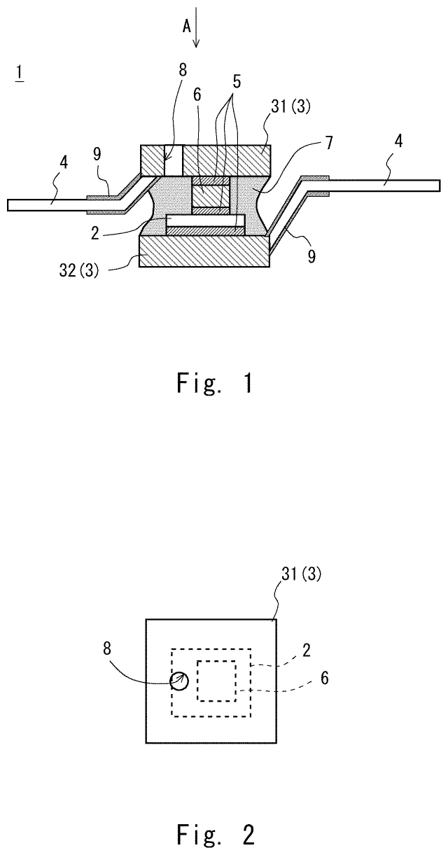

FIGS. 2 to 5 are schematic diagrams for specifically describing each step of the method for manufacturing a semiconductor module according to the first embodiment. First, as shown in FIG. 2, a penetrating hole 8 is formed in the upper lead frame 31 (penetrating hole forming step). In FIG. 2, the upper lead frame 31 is viewed from the direction of the arrow A in FIG. 1.

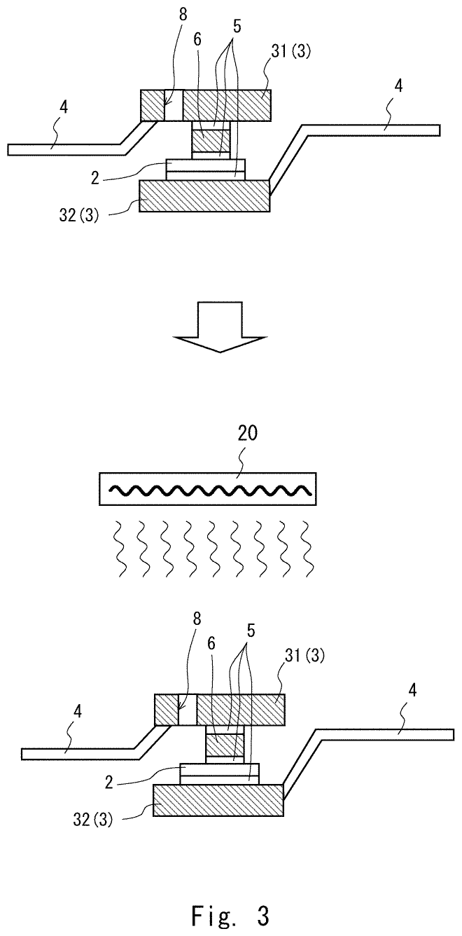

Next, as shown in the upper part of FIG. 3, the semiconductor element 2 is disposed on the lower lead frame 32, the spacer 6 is disposed on the semiconductor element 2, and the upper lead frame 31 is disposed on the spacer 6 (disposing step). Note that the solder 5 is disposed between the lower lead frame 32 and the semiconductor element 2, between the semiconductor element 2 and the spacer 6, and between the spacer 6 and the upper lead frame 31. Next, as shown in the lower part of FIG. 3, the disposed solder 5 is heated and melted by the heater 20 to couple the pair of lead frames 3 to the semiconductor element 2 (reflow step).

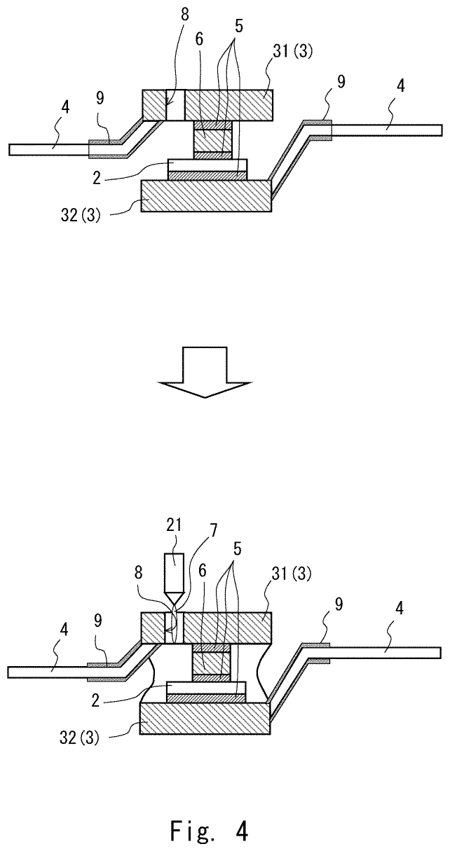

Next, as shown in the upper part of FIG. 4, the end part of the lead terminal 4 protruding from the upper lead frame 31 on the side of the end part connected to the upper lead frame 31 is coated with the insulating material 9 such as a fluororesin (coating step). Likewise, the end part of the lead terminal 4 protruding from the lower lead frame 32 on the side of the end part connected to the lower lead frame 32 is coated with the insulating material 9 (coating step). In the semiconductor module 1, it is necessary to properly insulate the semiconductor element 2 and the lead terminal 4 from each other. The end parts of the lead terminals 4 on the sides connected to the pair of lead frames 3 are close to the semiconductor element 2. By coating these end parts with the insulating material 9, it is possible to more satisfactorily insulate the semiconductor element 2 and the lead terminal 4 from each other.

Next, as shown in the lower part of FIG. 4, the underfill material 7, which is a liquid thermosetting resin, is injected from the penetrating hole 8 by the dispenser 21 to fill the region sandwiched between the pair of lead frames 3 the underfill material 7 (resin filling step). Here, the underfill material 7 is, for example, a composite resin mainly composed of an epoxy resin. To the underfill material 7, an inorganic filler such as silica and alumina for lowering the thermal expansion coefficient and improving the resin strength and an organic filler for reducing the stress and improving the adhesive strength are added, in addition to the base component and curing agent that serve as a base. Alumina in the inorganic filler has an effect of promoting heat conduction from the semiconductor element 2, which is a heat generator, to the upper lead frame 31 and the lower lead frame 32, which are heat spreaders, thereby improving the heat dissipation efficiency. When the underfill material 7 is injected from the penetrating hole 8 of the upper lead frame 31, the resin can easily enter the region sandwiched between the upper lead frame 31 and the lower lead frame 32. Thus, the region can be appropriately filled with the underfill material 7 in such a way that the content of the additive such as an inorganic filler becomes more uniform. Further, it has been confirmed through experiments by the inventors that the time required for the filling can be shortened by injecting the underfill material 7 from the penetrating hole 8 of the upper lead frame 31.

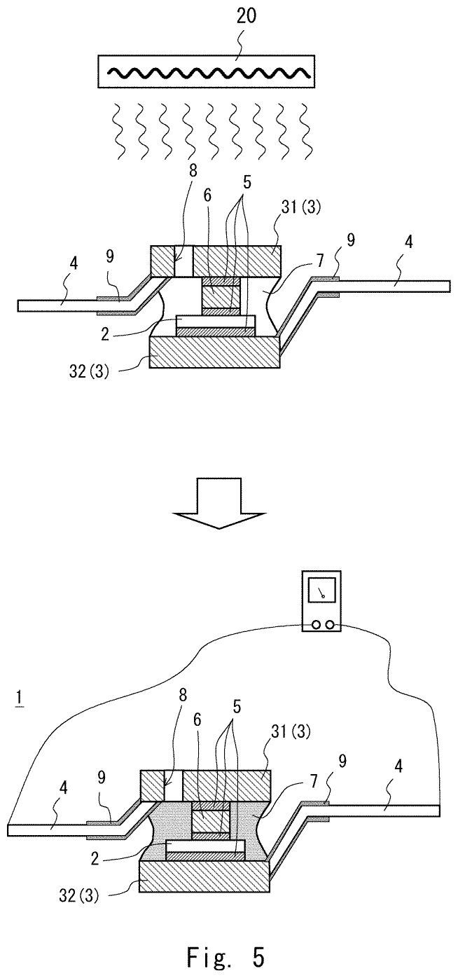

Next, as shown in the upper part of FIG. 5, the filled underfill material 7 is heated and cured by a heater 20 at a predetermined temperature (e.g., 140° C.) (resin curing step). Next, as shown in the lower part of FIG. 5, an electrical inspection is conducted on the completed semiconductor module 1 (inspection step).

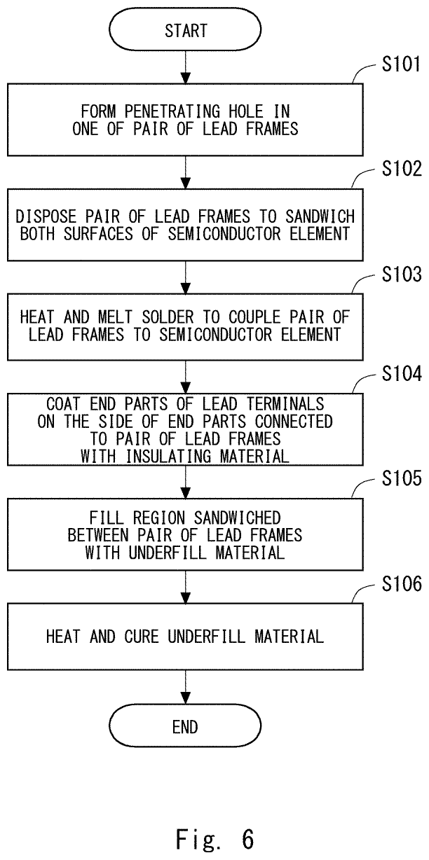

FIG. 6 is a flowchart showing a process flow of the method for manufacturing the semiconductor module 1 according to the first embodiment. Note that in the following descriptions, FIG. 1 is also referred to as appropriate. As shown in FIG. 6, first, the penetrating hole 8 is formed in at least one place in one of the pair of lead frames 3 (Step S101). Next, the pair of lead frames 3 is disposed so as to sandwich both surfaces of the semiconductor element 2 (Step S102). The solder 5 is disposed between the pair of lead frames 3 and the semiconductor element 2. Next, the disposed solder 5 is heated and melted to couple the pair of lead frames 3 to the semiconductor element 2 (Step S103).

After Step S103, the end parts of the lead terminals 4 on the side of the end parts connected to the pair of lead frames 3 are coated with the insulating material 9 (Step S104). Next, the underfill material 7 which is a liquid thermosetting resin is injected from the penetrating hole 8 to fill the region between the pair of lead frames 3 with the underfill material 7 (Step S105). Next, the underfill material 7 poured in the region sandwiched between the pair of lead frames 3 is heated and cured (Step S106).

In this manner, in the method for manufacturing a semiconductor module according to the first embodiment, the underfill material 7 which is a liquid thermosetting resin is injected by the dispenser 21 from the penetrating hole 8 formed in the upper lead frame 31 into the region sandwiched between the frame 31 and the lower lead frame 32. When the resin is injected from the penetrating hole 8 of the upper lead frame 31 in this way, the resin can easily enter the region sandwiched between the upper lead frame 31 and the lower lead frame 32, and thus the region can be appropriately filled with the resin. Further, the time required for the filling can be shortened.

### Second Embodiment

A second embodiment of the present disclosure will be described below with reference to the drawings.

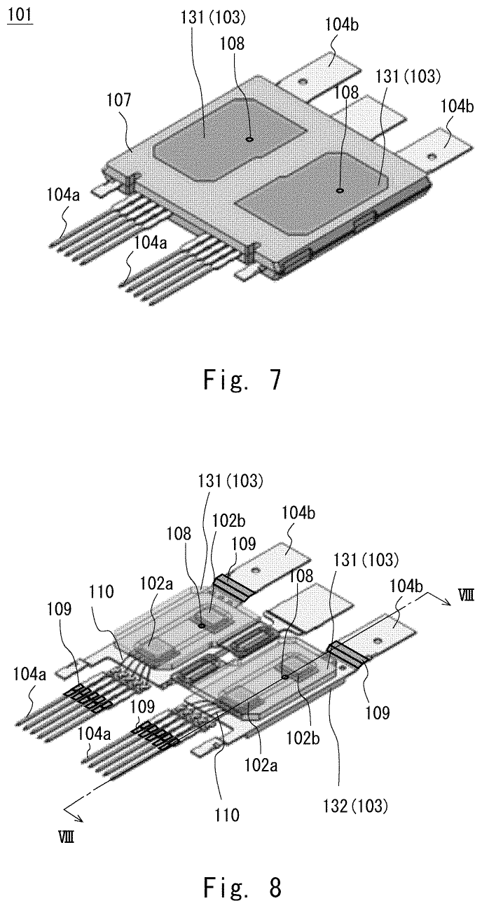

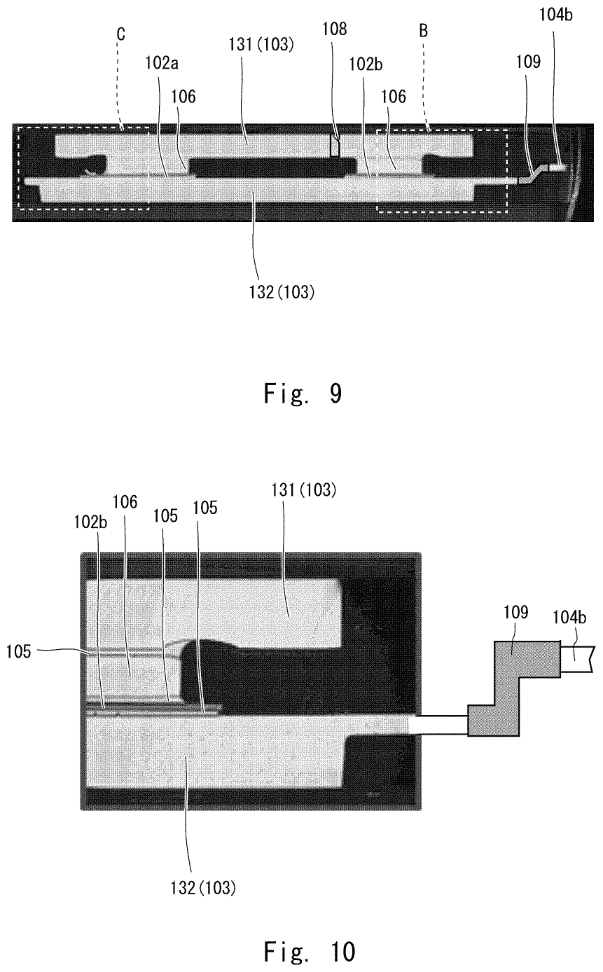

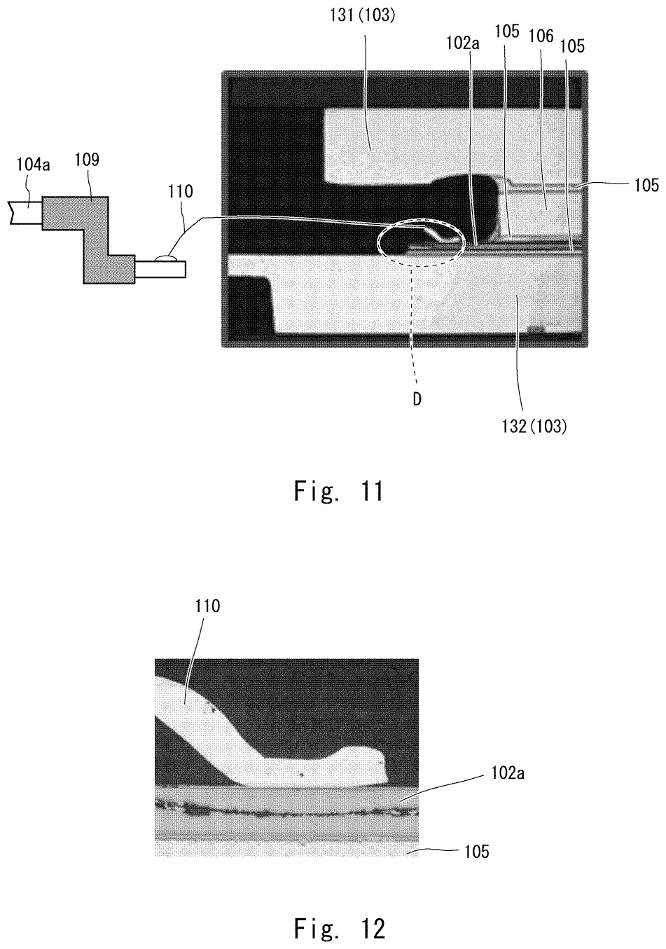

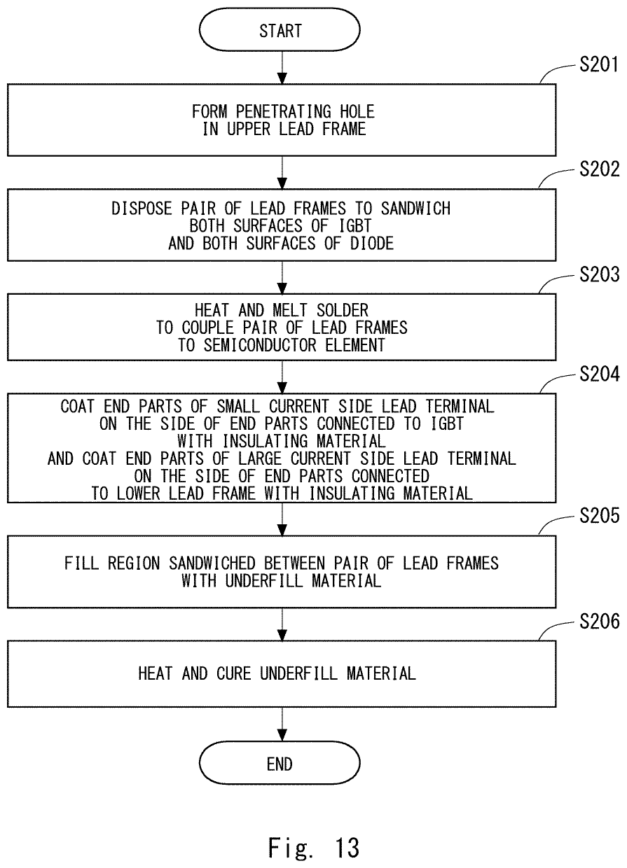

First, a configuration of a semiconductor module to which a method for manufacturing a semiconductor module according to the second embodiment is applied will be described with reference to FIGS. 7 to 12. FIG. 7 is a perspective view showing an external appearance of a semiconductor module 101 to which the method for manufacturing a semiconductor module is applied according to the second embodiment. FIG. 8 is a perspective view showing a state in which a part of the semiconductor module 101 shown in FIG. 7 sealed with an underfill material 107 is removed from the semiconductor module shown in FIG. 7. FIG. 9 is a cross-sectional view taken along the line VIII-VIII in FIG. 8. FIG. 10 is an enlarged view of a region B of FIG. 9. FIG. 11 is an enlarged view of a region C in FIG. 9. FIG. 12 is an enlarged view of a region D in FIG. 11.

As shown in FIG. 7, the outside of the semiconductor module 101 is sealed with the underfill material 107. Further, as shown in FIG. 8, the semiconductor module 101 includes IGBTs 102a and diodes 102b as semiconductor elements, upper lead frames 131 and lower lead frames 132 that are pairs of lead frames 103, small current side lead terminals 104a, and large current side lead terminals 104b.

As shown in FIGS. 8 and 9, the upper lead frame 131 and the lower lead frame 132, which are the pair of lead frames 103, are disposed to face each other on both surfaces of the IGBTs 102a and both surfaces of the diodes 102b. The upper lead frame 131 and the lower lead frame 132 are thin metal plates used as internal wiring in the semiconductor module 101 and are formed of metal having high electrical conductivity such as copper. Further, the upper lead frame 131 and the lower lead frame 132 are positioned between the semiconductor element 102, which is a heat generator, and a radiator. The upper lead frame 131 and the lower lead frame 132 also serve as heat spreaders which are buffers for improving the heat dissipation efficiency of the radiator.

Penetrating holes 108 are formed in the upper lead frames 131. Each of the penetrating holes 108 is formed in the vicinity of the semiconductor element having the largest amount of heat generation among the plurality of semiconductor elements present in the semiconductor module 101. The semiconductor module 101 includes the IGBTs 102a and the diodes 102b which are semiconductor elements, and between the IGBTs 102a and the diodes 102b, the diodes 102b have a larger amount of heat generation. Thus, each of the penetrating holes 108 is formed in the vicinity of the diode 102b. Each region sandwiched between the upper lead frame 131 and the lower lead frame 132 is filled with the underfill material 107 (see FIG. 7) which is a thermosetting resin.

As shown in FIGS. 9 and 10, each the diode 102b is coupled to the upper lead frame 131 with a spacer 106 interposed therebetween. The spacer 106 is made of the same metal as that of the upper lead frame 131. Each upper lead frame 131 is coupled to the spacer 106 by the solder 105, each spacer 106 is coupled to the diode 102b by the solder 105, and each diode 102b is coupled to the lower lead frame 132 by the solder 105. The solder 105 is reflow solder.

As shown in FIGS. 9 and 11, each IGBT 102a is coupled to the corresponding upper lead frame 131 with the corresponding spacer 106 interposed therebetween. Each upper lead frame 131 is coupled to the corresponding spacer 106 by the solder 105, each spacer 106 is coupled to the corresponding IGBT 102a by the solder 105, and each IGBT 102a is coupled to the corresponding lower lead frame 132 by the solder 105.

As shown in FIGS. 8, 9, and 10, each large current side lead terminal 104b protrudes from the corresponding lower lead frame 132. Each end part of the corresponding large current side lead terminal 104b on the side of the end part connected to the corresponding lower lead frame 132 is coated with an insulating material 109 such as a fluororesin.

As shown in FIGS. 8, 11 and 12, each small current side lead terminal 104a is connected to the corresponding IGBT 102a via an aluminum wire 110. Each end part of the corresponding small current side lead terminal 104a on the side of the end part connected to the corresponding IGBT 102a is coated with the insulating material 109.

Next, a process flow of the method for manufacturing the semiconductor module 101 according to the second embodiment will be described. In the following descriptions, FIGS. 8 and 9 are also referred to as appropriate.

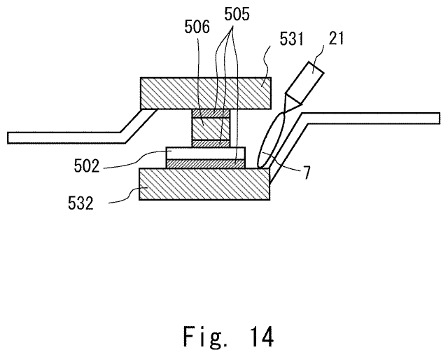

FIG. 13 is a flowchart showing a process flow of the method for manufacturing the semiconductor module 101 according to the second embodiment. As shown in FIG. 13, first, the penetrating holes 108 are formed in the upper lead frames 131 (Step S201). Next, each pair of lead frames 103 is disposed in such a way that both surfaces of the corresponding IGBT 102a and the corresponding diode 102b, which are semiconductor elements, are sandwiched between the corresponding upper lead frame 131 and the corresponding lower lead frame 132 which are the pair of lead frames 103 (Step S202). The solder 105 is disposed between each upper lead frame 131 and the corresponding spacer 106, between each spacer 106 and the corresponding IGBT 102a and the corresponding diode 102b, and between each IGBT 102a and the corresponding diode 102b and the corresponding lower lead frame 132. Next, the disposed solder 105 is heated and melted, and the pair of lead frames 3, the IGBT 102a, and the diode 102b are coupled (Step S203).

After Step S203, the end part of each small current side lead terminal 104a on the side of the end part connected to the corresponding IGBT 102a is coated with the insulating material 109, and the end part of each large current side lead terminal 104b on the side of the end part connected to the corresponding lower lead frame 132 is coated with the insulating material 109 (Step S204). Next, the underfill material 107, which is a liquid and thermosetting resin, is injected from the penetrating holes 108, and the regions between the pairs of lead frames 103 are filled with the underfill material 107 (Step S205). Next, the underfill material 107 poured in the regions sandwiched between the pairs of lead frames 103 are heated and cured (Step S206).

As described above, in the method for manufacturing a semiconductor module according to the second embodiment, each penetrating holes 108 is formed in the vicinity of the semiconductor element having the largest amount of heat generation among the plurality of semiconductor elements present in the semiconductor module 101, that is, in the vicinity of the diode 102b. Commonly, an additive such as alumina for promoting the heat conduction is added to the underfill material 107 poured in the semiconductor module 101. When the underfill material 107 is injected from the penetrating hole 108, in the region sandwiched between the pair of lead frames 103, a content ratio of the additive in the underfill material 107 at a position close to the penetrating hole 108 is closer to the content ratio of the additive in the underfill material 107 before the underfill material 107 is injected than a content ratio of the additive in the underfill material 107 at a position far from the penetrating hole 108 is. In other words, the content ratio of the additive contained in the underfill material 107 at the position closer to the penetrating hole 108 is higher than that at the position farther from the penetrating hole 108. Therefore, in the semiconductor module 101, by forming the penetrating holes 108 in the vicinity of the diodes 102b, which are the semiconductor elements having large amounts of heat generation, it is possible to efficiently dissipate heat of the diodes 102b.

Note that the present disclosure is not limited to the above-described embodiments and can be changed as appropriate without departing from the spirit of the present disclosure.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A method for manufacturing a semiconductor module comprising:
a semiconductor element;
a pair of lead frames disposed to face each other on both surfaces of the semiconductor element; and
a lead terminal protruding from each one of the pair of lead frames, the method comprising:
forming a penetrating hole in at least one place on one of the pair of lead frames;
disposing the pair of lead frames so as to sandwich the both surfaces of the semiconductor element;
injecting a liquid thermosetting resin through the penetrating hole to fill a region sandwiched between the pair of lead frames with the resin; and
heating and curing the resin the region is filled with.

2. The method according to claim 1, wherein
a plurality of the semiconductor elements are present in the semiconductor module, and
the penetrating hole is formed in the vicinity of a semiconductor element having a largest amount of heat generation among the plurality of the semiconductor elements present in the semiconductor module.

3. The method according to claim 1, further comprising coating an end part of the lead terminal on a side connected to the pair of lead frames with an insulating material.
